(19) United States
(12) Patent Application Publication
(10) Pub. No.: US 2023/0131661 A1
(43) Pub. Date: Apr. 27, 2023

(54) DISPLAY DEVICE

(71) Applicant: Japan Display Inc., Tokyo (JP)

(72) Inventor: Takeo KOITO, Tokyo (JP)

(21) Appl. No.: 17/969,008

(22) Filed: Oct. 19, 2022

(30) Foreign Application Priority Data
Oct. 25, 2021 (JP) 2021-173572

(51) Int. Cl. G02F 1/1335; G02F 1/13357

(52) U.S. Cl. CPC G02F 1/133553; G02F 1/13362; G02F 1/133512; G02F 1/133606; H01L 33/60

(57) ABSTRACT

According to an aspect, a display device includes: a plurality of pixels arranged in a first direction; a light source configured to emit light to the pixels; a light-blocking member disposed between the pixels and the light source and provided with slits extending in a direction intersecting the first direction; a first reflector that faces the light-blocking member with the light source in between and reflects light to the light-blocking member; a second reflector that covers at least part of the light source side of the light-blocking member and reflects light to the light source; and a reflective polarizer that is disposed between the first reflector and the pixels, transmits light polarized in a second direction, and reflects light polarized in a direction intersecting the second direction.

### CROSS-REFERENCE TO RELATED APPLICATION

This application claims the benefit of priority from Japanese Patent Application No. 2021-173572 filed on Oct. 25, 2021, the entire contents of which are incorporated herein by reference.

### BACKGROUND

### 1. Technical Field

What is disclosed herein relates to a display device.

### 2. Description of the Related Art

As described in Japanese Patent Application Laid-open Publication No. 2012-203231 (JP-A-2012-203231), a liquid crystal display device capable of outputting images individually to a plurality of viewpoints is known. In the liquid crystal display device of JP-A-2012-203231, a path on which light from a light source that is transmitted through a pixel and reaches a user’s eye is limited by a light-blocking layer provided with a slit.

However, in a system of using only light having passed through the slit as disclosed in JP-A-2012-203231, light blocked by the light-blocking layer among light from the light source does not completely contributes image output. Thus, with the system disclosed in JP-A-2012-203231, the utilization efficiency of light from the light source is extremely low. Furthermore, the luminance of light from the light source needs to be increased to increase the luminance of an output image in the system disclosed in JP- A-2012-203231; however, since the light utilization efficiency is extremely low as described above, the efficiency of luminance increase relative to cost such as electric power consumption needed to increase the luminance of light from the light source is extremely low.

For the foregoing reasons, there is a need for a display device capable of outputting images individually to a plurality of viewpoints and more efficiently using light from a light source.

### SUMMARY

According to an aspect, a display device includes: a plurality of pixels arranged in a first direction; a light source configured to emit light to the pixels; a light-blocking member disposed between the pixels and the light source and provided with slits extending in a direction intersecting the first direction; a first reflector that faces the light-blocking member with the light source in between and reflects light to the light-blocking member; a second reflector that covers at least part of the light source side of the light-blocking member and reflects light to the light source; and a reflective polarizer that is disposed between the first reflector and the pixels, transmits light polarized in a second direction, and reflects light polarized in a direction intersecting the second direction.

### BRIEF DESCRIPTION OF THE DRAWINGS

FIG. 1 is a schematic diagram illustrating a mechanism of a method of outputting different images to different viewpoints, respectively;

FIG. 2 is a schematic diagram illustrating a main configuration in a first example;

FIG. 3 is a schematic diagram illustrating a main configuration in a second example;

FIG. 4 is a graph illustrating a luminance of a pixel visually recognized by a user in each of a reference example and the first and second examples;

FIG. 5 is a schematic diagram illustrating an exemplary form of a display device to which the first example is applied;

FIG. 6 is a schematic diagram illustrating an exemplary specific configuration of a light source;

FIG. 7 is a schematic diagram illustrating an exemplary form of a display device to which the second example is applied;

FIG. 8 is a schematic diagram illustrating an exemplary form of a display device to which the second example is applied;

FIG. 9 is a schematic diagram illustrating an exemplary configuration of a multilayered structural body;

FIG. 10 is a schematic diagram illustrating an exemplary configuration of a multilayered structural body;

FIG. 11 is a schematic diagram illustrating an exemplary configuration of a multilayered structural body;

FIG. 12 is a graph illustrating difference in luminance of a pixel between a case in which a multilayered structural body is disposed between a display panel and the light source in a configuration described with reference to FIG. 8, a case in which another multilayered structural body is disposed therebetween, and a case in which yet another multilayered structural body is disposed therebetween;

FIG. 13 is a schematic sectional view illustrating an exemplary configuration of a reflective layer and a light-blocking layer;

FIG. 14 is a schematic diagram illustrating a mechanism that crosstalk is caused by reflected light that is generated through a combination of light reflection by a signal line and light reflection by the reflective layer;

FIG. 15 is a schematic diagram illustrating a mechanism that the crosstalk is reduced by light-blocking layers; and

FIG. 16 is a schematic diagram illustrating an exemplary correspondence relation between the arrangement direction of first pixels, second pixels, and third pixels and the extending direction of light-blocking layers and slits.

### DETAILED DESCRIPTION

An embodiment of the present disclosure is described below with reference to the drawings. What is disclosed herein is only an example, and any changes that can be easily conceived by those skilled in the art while maintaining the main purpose of the invention are naturally included in the scope of the present disclosure. The drawings may be schematically represented in terms of the width, thickness, shape, etc. of each part compared to those in the actual form for the purpose of clearer explanation, but they are only examples and do not limit the interpretation of the present disclosure. In the present specification and the drawings, the same reference sign is applied to the same elements as those already described for the previously mentioned drawings, and detailed explanations may be omitted as appropriate.

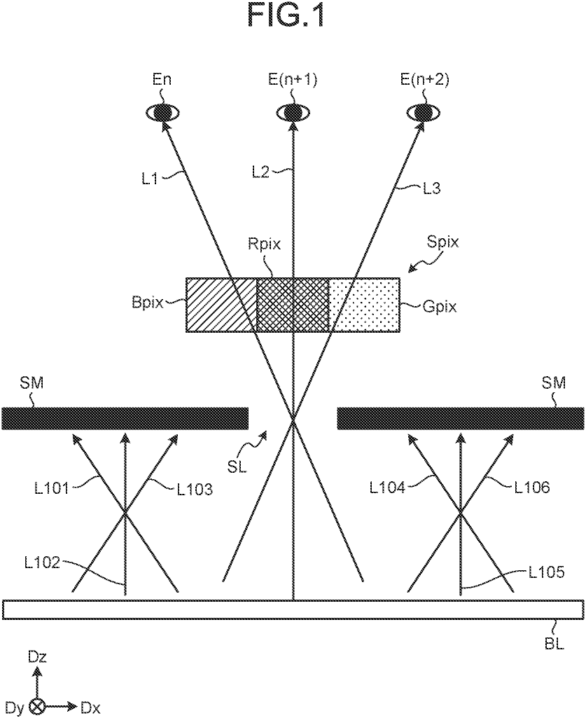

FIG. 1 is a schematic diagram illustrating a mechanism of a method of outputting different images to different viewpoints, respectively. In the following description, a first direction Dx is defined to be a direction along the arrangement direction of a first pixel Rpix, a second pixel Gpix, and a third pixel Bpix in FIG. 1. A second direction Dy is defined to be a direction orthogonal to the first direction Dx and along a panel plate surface of a display panel 40 (refer to FIG. 5) including the first pixel Rpix, the second pixel Gpix, and the third pixel Bpix. A third direction Dz is defined to be a direction orthogonal to the first direction Dx and the second direction Dy. A pixel Spix means any of the first pixel Rpix, the second pixel Gpix, and the third pixel Bpix without distinction among them.

Each of the pixels Spix controls the degree of transmission of light from the backlight BL. The pixels are included in a transmissive liquid crystal display configured to output an image to a side opposite to a backlight BL with the pixel Spix interposed therebetween. The first pixel Rpix can transmit light in a first color (for example, red (R)). The second pixel Gpix can transmit light in a second color (for example, green (G)). The third pixel Bpix can transmit light in a third color (for example, blue (B)). The colors of light transmitted by the first pixel Rpix, the second pixel Gpix, and the third pixel Bpix, respectively, depend on a color filter CF (refer to FIG. 5) to be described later. A unit pixel is composed of a set of the first pixel Rpix, the second pixel Gpix, and the third pixel Bpix. A display region is formed of the unit pixels disposed in a matrix having a row-column configuration. A pixel region of each pixel is a region partitioned by a plurality of scanning lines and signal lines provided in the display region. In the present embodiment, each pixel has a thickness extending from a pixel electrode to the color filter when viewed in the third direction Dz.

Light blocking members SM provided with slits SL are disposed between the pixels Spix and the backlight BL. The light-blocking member SM blocks light. When light emitted from the backlight BL reaches the light-blocking member SM, the light (for example, light L101, L102, L103, L104, L105, and L106 illustrated in FIG. 1) is blocked by the light-blocking member SM.

The slit SL is a gap provided between the light-blocking members SM. Light (for example, light L1, L2, and L3 illustrated in FIG. 1) emitted from the backlight BL and passing through the slit SL reaches the pixel Spix. The light transmitted through the pixel Spix is visually recognized by a user. Since the path of light that can pass through the pixel Spix is limited by the slit SL, a combination of light visually recognized at each of viewpoints En, E(n+1), and E(n+2) of the user and the pixel Spix through which the light passes is limited.

FIG. 1 exemplarily illustrates the light L1 passing through the third pixel Bpix and reaching the viewpoint En, the light L2 passing through the first pixel Rpix and reaching the viewpoint E(n+1), and the light L3 passing through the second pixel Gpix and reaching the viewpoint E(n+2). In this manner, the paths of light reaching the respective viewpoints En, E(n+1), and E(n+2) are set to be different from one another, whereby different images can be output to the different viewpoints. Images are output based on the mechanism described above with reference to FIG. 1 in, for example, a multi-view display output in which different images are visually recognized at different viewpoints and a 3D image display output using stereoscopic parallax images.

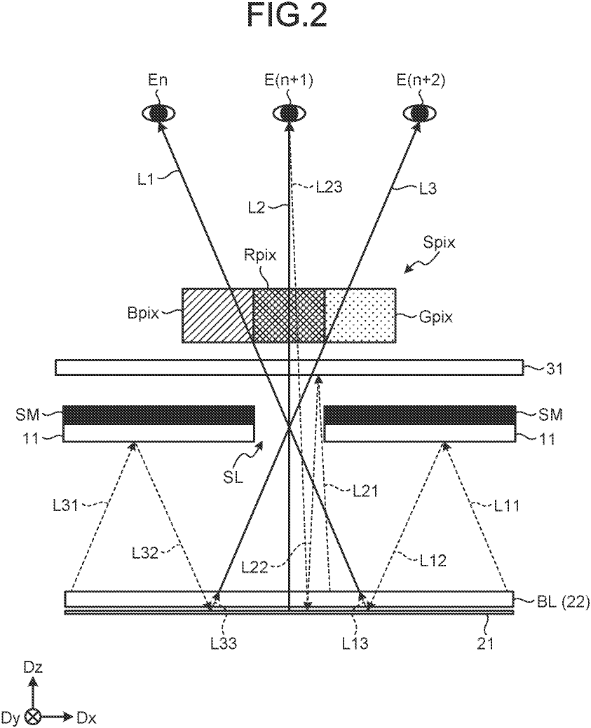

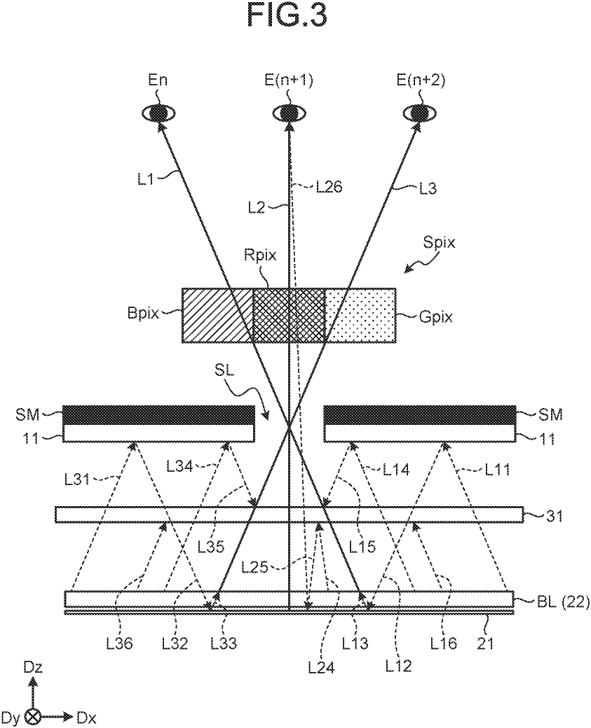

However, some light from the backlight BL, such as the light L101, L102, L103, L104, L105, and L106 illustrated in FIG. 1 does not contribute image output because of the light-blocking members SM provided to output different images to different viewpoints. In order to provide brighter image output, it is preferable to increase the amount of light passing through the slit SL. Thus, an embodiment of the present disclosure employs a configuration that can increase the amount of light passing through the slit SL as compared to the mechanism described above with reference to FIG. 1. Examples of the embodiment of the configuration will be described below with reference to FIGS. 2 and 3.

FIG. 2 is a schematic diagram illustrating a main configuration in a first example. As illustrated in FIG. 2, in the first example, a reflective layer 11 is provided on the backlight BL side of each of the light-blocking members SM. In addition, a reflective member 21 is provided on a side of the backlight BL opposite to the reflective layer 11 side of the backlight BL. The reflective layers 11 and the reflective member 21 reflect light. The backlight BL in the first example illustrated in FIG. 2 and a second example to be described later with reference to FIG. 3 has a configuration employing a light guiding member (for example, a light guiding plate 22 of a light source 20 illustrated in FIG. 5 to be described later) that can transmit light.

For example, light L11 illustrated in FIG. 2 is reflected by the reflective layer 11 and travels as a reflected light L12 through the backlight BL toward the reflective member 21. The reflected light L12 is reflected by the reflective member 21, follows, as a reflected light L13, the same path as that of the light L1, and travels through the slit SL and the third pixel Bpix to reach the viewpoint En. Thus, in the first example, the amount of light reaching the viewpoint En is increased by at least the reflected light L13 as compared to that in the configuration described above with reference to FIG. 1. Therefore, in the first example, the luminance of the pixel Spix (for example, the third pixel Bpix) when viewed from the user viewing the pixel Spix at the viewpoint En is increased as compared to that in the configuration described above with reference to FIG. 1.

Light L31 illustrated in FIG. 2 is reflected by the reflective layer 11 and travels through the backlight BL toward the reflective member 21 as a reflected light L32. The reflected light L32 is reflected by the reflective member 21, follows, as a reflected light L33, the same path as that of the light L3, and travels through the slit SL and the second pixel Gpix to reach the viewpoint E(n+2). Thus, in the first example, the amount of light reaching the viewpoint E(n+2) is increased by at least the reflected light L33 as compared to that in the configuration described above with reference to FIG. 1. Therefore, in the first example, the luminance of the pixel Spix (for example, the second pixel Gpix) when viewed from the user viewing the pixel Spix at the viewpoint E(n+2) is increased as compared to that in the configuration described above with reference to FIG. 1.

In addition, in the first example, a reflective polarization layer 31 is disposed between the light-blocking members SM and the pixels Spix as illustrated in FIG. 2. The reflective polarization layer 31 transmits light (first polarization component) polarized in one direction and reflects light (second polarization component) polarized in a direction different from the one direction. More specifically, for example, the reflective polarization layer 31 transmits a P wave as the first polarization component and reflects an S wave as the second polarization component orthogonal to the first polarization component. For example, light L21 illustrated in FIG. 2 passes through the slit SL. However, the light L21 is reflected by the reflective polarization layer 31, and travels as a reflected light L22 through the slit SL and the backlight BL toward the reflective member 21. The reflected light L22 is reflected by the reflective member 21 and travels toward the reflective polarization layer 31 again as a reflected light L23. This polarization component is reflected by the reflective polarization layer 31 again if the polarization component remains as the S wave, but the polarization component changes from the S wave to the P wave at a predetermined proportion while repeating such reflection. Then, the polarization component as the P wave reaches the viewpoint E(n+1) through the slit SL, the reflective polarization layer 31, and the first pixel Rpix. Therefore, in the first example, the amount of light reaching the viewpoint E(n+1) is increased by at least the reflected light L23 as compared to that in the configuration described above with reference to FIG. 1. Thus, in the first example, the luminance of the pixel Spix (for example, the first pixel Rpix) when viewed from the user viewing the pixel Spix at the viewpoint E(n+1) is increased as compared to that in the configuration described above with reference to FIG. 1.

Although not illustrated in FIG. 1, polarization layers each of which transmits a particular polarization component and blocks the other polarization component are provided on respective sides of the pixels Spix in the third direction Dz in the transmissive liquid crystal display. The polarization direction of the polarization component blocked by a polarization layer provided between the pixels Spix and the light-blocking members SM among the polarization layers is the same as that of the first polarization component reflected by the reflective polarization layer 31. Thus, the polarization component (for example, the P wave) reaching the pixel Spix as the light L1, L2, or L3 is limited in advance irrespective of whether the reflective polarization layer 31 is provided.

FIG. 3 is a schematic diagram illustrating a main configuration in the second example. In the second example as illustrated in FIG. 3, the reflective layers 11 are provided on the backlight BL side of the light-blocking members SM in the same manner as the first example. In addition, the reflective member 21 is provided on the side of the backlight BL opposite to the reflective layer 11 side of the backlight BL. However, unlike the first example, the reflective polarization layer 31 is not disposed between the light-blocking members SM and the pixels Spix in the second example. Instead, the reflective polarization layer 31 is disposed between the reflective layers 11 and the backlight BL in the second example.

For example, light L24 illustrated in FIG. 3 travels on a path passing through the slit SL, but is reflected by the reflective polarization layer 31 and travels through the backlight BL toward the reflective member 21 as a reflected light L25. The reflected light L25 is reflected by the reflective member 21, travels through the reflective polarization layer 31, the slit SL, and the first pixel Rpix as a reflected light L26, and reaches the viewpoint E(n+1). That is, light reaching the viewpoint E(n+1) in the embodiment includes not only light that directly reaches the viewpoint (for example, the S wave as the first polarization component) without reflection by the reflective member 21 but also light that becomes the S wave through reflection by the reflective member 21. Thus, in the second example, the amount of light reaching the viewpoint E(n+1) is increased by at least the reflected light L26 as compared to that in the configuration described above with reference to FIG. 1.

Part of the light L11 and L31 and the reflected light L12 and L22 described above with reference to FIG. 2 is potentially reflected by the reflective polarization layer 31 between the reflective layers 11 and the backlight BL, which might hamper the part of the light from traveling through the paths described above with reference to FIG. 2. However, in the second example, light L14 and L15 (or light L34 and L35) is emitted from the backlight BL, transmitted through the reflective polarization layer 31, reflected by the reflective layer 11, then reflected on the reflective layer 11 side of the reflective polarization layer 31, and finally joins the same path as that of the light L1 (or the light L3). In addition, in the second example, light L16 (or light L36) is emitted from the backlight BL, reflected on the backlight BL side of the reflective polarization layer 31, and finally joins the same path as that of the reflected light L12 (or the reflected light L32). Since the light such as these exemplarily described light L14, L15, L16, L34, L35, and L36 is reflected by the reflective polarization layer 31 between the reflective layers 11 and the backlight BL and passes through the slit SL, a proportion of light passing through the slit SL to the light emitted from the backlight BL further increases in the second example than in the first example. Thus, the luminance of the pixel Spix when viewed from the user further increases in the second example than in the first example. As for a pixel (for example, the first pixel Rpix) opposing the backlight BL with the slit SL interposed therebetween in the third direction Dz, the first polarization component (for example, the S wave) of light traveling from the backlight BL toward in the third direction Dz passes through the reflective polarization layer 31 and reaches the pixel; and light components other than the first polarization component are reflected to travel toward the reflective member 21, then polarized in the same direction as the first polarization component through further reflection by the reflective member 21, and finally reaches the pixel. Thus, brighter image output is achieved than in a case in which neither reflective polarization layer 31 nor reflective member 21 is provided. As for a pixel (for example, the second pixel Gpix or the third pixel Bpix) disposed opposing the backlight BL with the slit SL interposed therebetween in a direction different from the third direction Dz, light from the backlight BL reaches the pixel through reflection by the reflective polarization layer 31 and the reflective member 21, which would not reach the pixel as a light emission line from the backlight BL without the reflective polarization layer 31 and the reflective member 21. Thus, brighter image output is achieved.

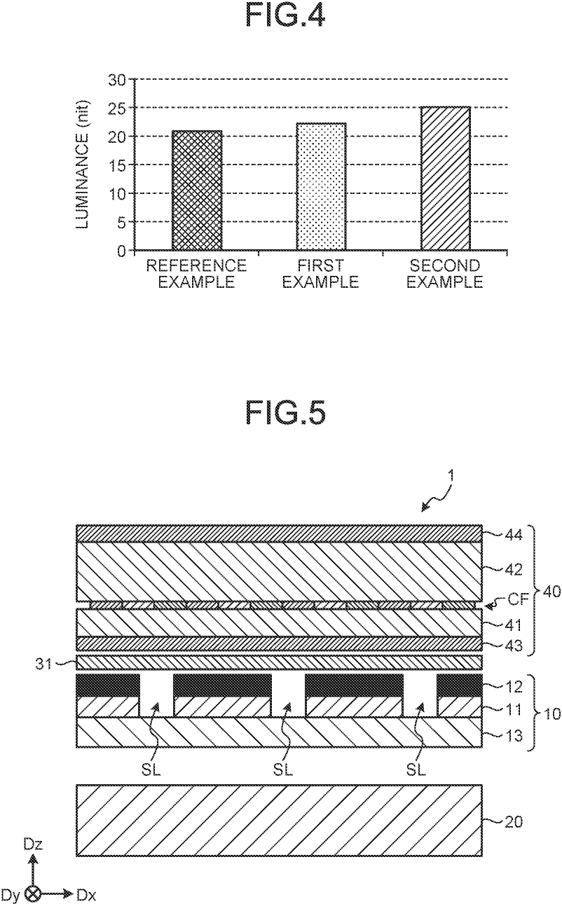

FIG. 4 is a graph illustrating the luminance of a pixel Spix visually recognized by the user in each of a reference example and the first and second examples. The reference example corresponds to the configuration example described above with reference to FIG. 1. As illustrated in FIG. 4, the luminance of the pixel Spix is further increased in the second example than in the reference example and the first example (refer to FIG. 2). The luminance of the pixel Spix is further increased in the first example than in the reference example.

Specific exemplary forms of a display device to which the first example or the second example is applied will be described below with reference to FIGS. 5 to 13.

FIG. 5 is a schematic diagram illustrating an exemplary form of a display device 1 to which the first example is applied. The display device 1 includes the display panel 40 and a parallax panel 10 facing each other with the reflective polarization layer 31 interposed therebetween. In the display device 1, the light source 20 is provided on a side of the parallax panel 10 opposite to the reflective polarization layer 31 side of the parallax panel 10.

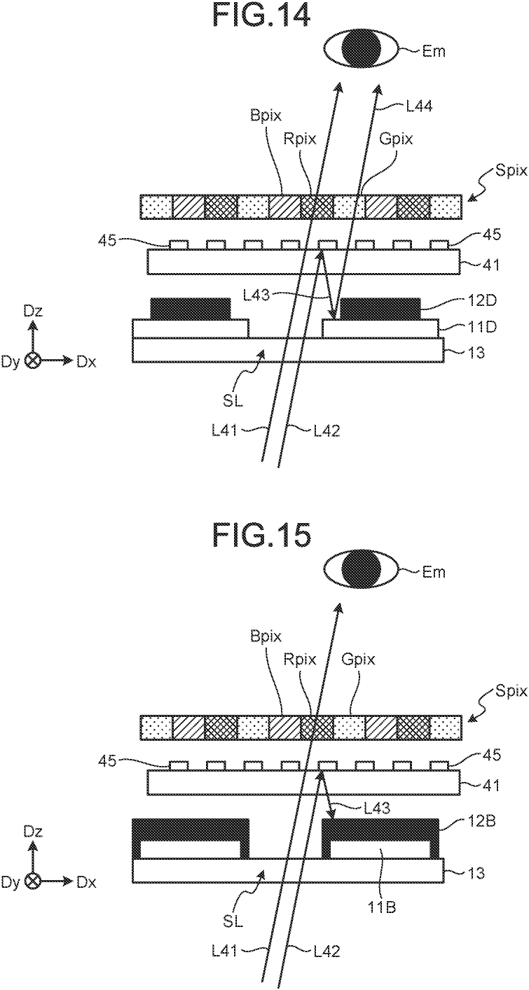

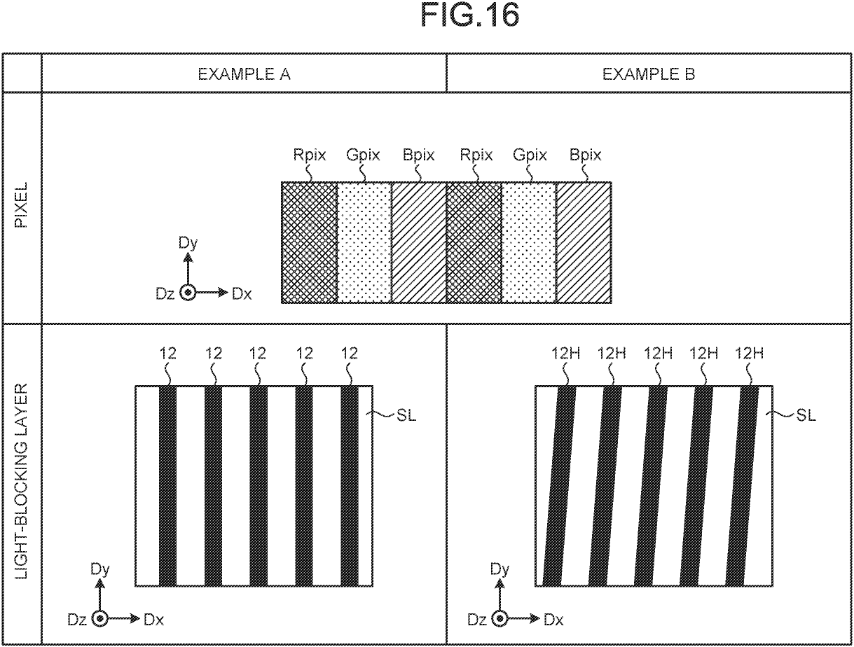

The display panel 40 includes a first substrate 41, a second substrate 42, and polarization layers 43 and 44. The first substrate 41 is a light-transmitting substrate on which pixel electrodes, switching elements, signal lines 45 (refer to FIGS. 14 and 15), scanning lines, a source driver, a gate driver, and the like are mounted. The pixel electrode is individually provided for each pixel Spix. One of the source and drain of each switching element is coupled to the pixel electrode, and the other of the source and drain of each switching element is coupled to a corresponding one of the signal lines 45. The scanning lines transmit drive signals to be provided to the gates of the switching elements. The source driver is a circuit configured to output, to the signal lines 45, pixel signals to be provided to the pixels Spix based on an image signal input to the display panel 40 so that the pixel signals are provided to the respective pixels Spix. The gate driver is a circuit configured to output the drive signals to the scanning lines in accordance with the output timing of the pixel signals. The second substrate 42 is a light-transmitting substrate provided with the color filter CF or the like that transmits light in a color corresponding to a spectrum peak of light that is output at each pixel Spix. The present disclosure is not limited thereto but may employ a configuration in which the color filter is provided on the first substrate 41 side. A common electrode having constant potential and shared by a plurality of the pixels Spix is provided on either one of the first substrate 41 and the second substrate 42. Although not illustrated, liquid crystal is enclosed between the first substrate 41 and the second substrate 42. Each of the polarization layers 43 and 44 is a polarization plate or polarization film that transmits a particular polarization component and blocks the other polarization component. The polarization layer 43 is provided on the reflective polarization layer 31 side of the first substrate 41. The polarization layer 44 is provided on the user side of the second substrate 42. The luminance of light to be transmitted through the display panel 40 is controlled for each of the pixels Spix by a combination of a polarization component transmitted through the polarization layers 43 and 44 and control of a polarization component by liquid crystal molecule, the orientation of which is controlled in accordance with the pixel signal.

In the configuration according to the present disclosure, the thickness of the first substrate 41 in the third direction Dz is less than that of the second substrate 42. The first substrate 41 is subjected to chemical mechanical polishing (CMP), and thus, thinner than the second substrate 42. The substrate surface of the first substrate 41 on which a multilayered structure for mounting the switching elements, the signal lines 45, and the like described above is formed can be flattened at higher accuracy by the CMP.

In the configuration illustrated in FIG. 5, the first polarization component transmitted through the reflective polarization layer 31 is identical to the polarization component transmitted through the polarization layer 43. The reflective polarization layer 31 is, for example, a thin-film optical member in which a plurality of kinds of polymer materials are dispersed. The reflective polarization layer 31 selectively transmits the first polarization component and reflects the second polarization component by using a refractive index difference between at least two kinds of polymer materials. The reflective polarization layer 31 is not limited to the above-described configuration but may be configured as a wire grid reflective polarizer, a cholesteric reflective polarizer, or a dispersive reflective polarization film.

The parallax panel 10 includes the reflective layer 11, a light-blocking layer 12, and a light-transmitting substrate 13. The light-transmitting substrate 13 is a substrate having one surface (for example, a surface on the reflective polarization layer 31 side) on which the reflective layer 11 and the light-blocking layer 12 are stacked. The light-transmitting substrate 13, the first substrate 41, and the second substrate 42 are, for example, glass substrates but may be light-transmitting substrates made of another material.

The reflective layer 11 is a thin-film reflective layer formed of a material, such as chromium (Cr), which has light reflective glazing. The reflective layer 11 is formed closer to the light source 20 than the light-blocking layer 12 is. The light-blocking layer 12 is a thin-film light-blocking layer formed of a black material, such as oxidize chromium (CrO₂), which absorbs light. The light-blocking layer 12 functions as the above-described light-blocking member SM. The above-described slits SL are provided to the reflective layers 11 and the light-blocking layers 12.

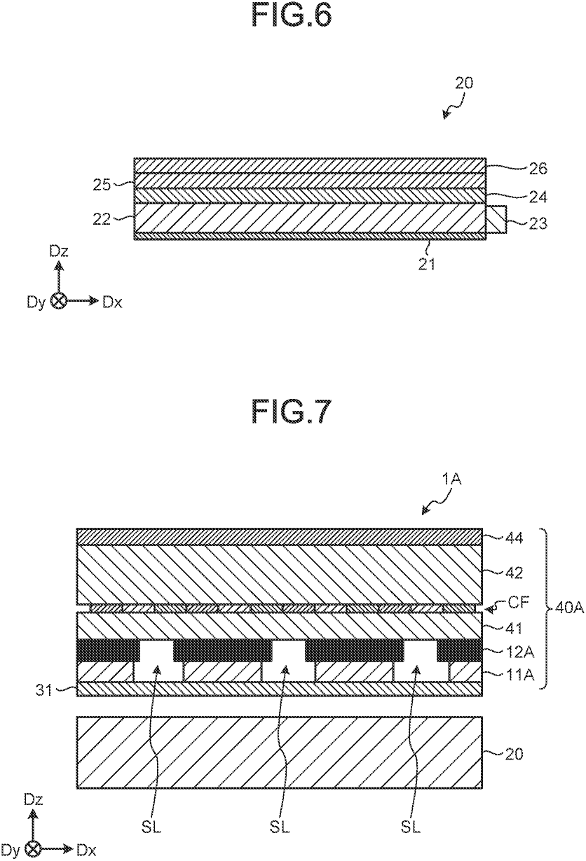

FIG. 6 is a schematic diagram illustrating an exemplary specific configuration of the light source 20. The light source 20 functions as the above-described backlight BL and includes the reflective member 21. As illustrated in, for example, FIG. 6, the light source 20 includes the reflective member 21, the light guiding plate 22, a light-emitting element 23, a diffusion layer 24, and prism sheets 25 and 26. The components included in the light source 20 except for the light-emitting element 23 are disposed in the order of the prism sheet 26, the prism sheet 25, the diffusion layer 24, the light guiding plate 22, and the reflective member 21 when viewed from the parallax panel 10 side. The light-emitting element 23 is positioned on a lateral side of the light guiding plate 22 (for example, in the first direction Dx relative to the light guiding plate 22).

The reflective member 21 is a sheet-like or film-like optical member that specularly reflects, to the parallax panel 10 side, light from the light guiding plate 22. The light guiding plate 22 is a plate member that transmits light. The light guiding plate 22 is, for example, a colorless acrylic plate but not limited thereto and may be made of another material that similarly functions. The light-emitting element 23 emits light into the light guiding plate 22. The light-emitting element 23 is, for example, a white light-emitting diode (LED) but not limited thereto and may be a combination of light-emitting elements emitting light in a plurality of colors (for example, R, G, and B) provided to generate a color that is recognized as white. Most of light emitted from the light-emitting element 23 into the light guiding plate 22 is reflected by the reflective member 21 and is output toward the diffusion layer 24 side.

The diffusion layer 24 is an optical member in which a diffusion material is dispersed in a light-transmitting resin (for example, methyl polymethacrylate resin) formed in a thin-film shape or a plate shape. The diffusion material is employed to diffuse light. The diffusion material contains, for example, any one or more of glass, polystyrene beads, and calcium carbonate but may be another material that similarly functions.

The prism sheets 25 and 26 are each a prism sheet (lens sheet) that causes more uniform light to be diffused from the diffusion layer 24 side to the parallax panel 10 side by using, for example, a prism formed in a thin film shape, but are not limited thereto and may be other optical members that can cause characteristics of light emitted from the light source 20 toward the parallax panel 10 side to be more suitable for image output. By the diffusion layer 24 and the prism sheets 25 and 26, light that is output from the light guiding plate 22 is more uniformly incident in the entire display region of the display panel 40 in which the pixels Spix are disposed.

FIG. 7 is a schematic diagram illustrating an exemplary form of a display device 1A to which the second example is applied. The display device 1A includes a display panel 40A and the light source 20 facing each other with the reflective polarization layer 31 interposed therebetween. The display panel 40A has a configuration in which the polarization layer 43 in the display panel 40 is omitted and light-blocking layers 12A, reflective layers 11A, and the reflective polarization layer 31 are stacked from the first substrate 41 side toward the light source 20 side at the position where the polarization layer 43 is provided in the display panel 40.

Each light-blocking layer 12A is formed such that the light-blocking layer 12A has a greater width in the first direction Dx than that of a reflective layer 11A overlapping the light-blocking layer 12A in a plan view and is formed to completely cover the reflective layer 11A overlapping the light-blocking layer 12A in a plan view. A plan view is a front view of a plane aligned with the first direction Dx and the second direction Dy. Each light-blocking layer 12A is formed as a thin film on a surface of the first substrate 41 on the light source 20 side.

Each reflective layer 11A is formed such that the reflective layer 11A has a width in the first direction Dx less than that of a light-blocking layer 12A overlapping the reflective layer 11A in a plan view and is rimmed by the light-blocking layer 12A overlapping the reflective layer 11A in a plan view. If the reflective layers 11A and the light-blocking layers 12A that overlap each other are viewed from the reflective layer 11A side, an end part of each of the light-blocking layers 12A seems to be exposed so that the light-blocking layer 12A rims the corresponding one of the reflective layers 11A arranged in the first direction Dx with the slit SL interposed therebetween.

The display device 1A has the same configuration as the display device 1 except for features otherwise described above. The form of a display device to which the second example is applied is not limited to the display device 1A.

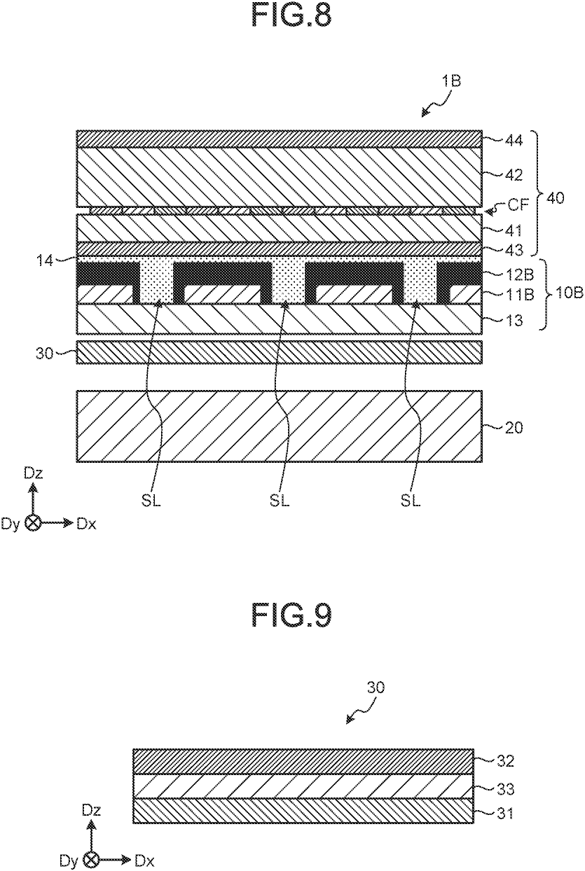

FIG. 8 is a schematic diagram illustrating an exemplary form of a display device 1B to which the second example is applied. The display device 1B has a configuration in which the parallax panel 10 of the display device 1 described above with reference to FIG. 5 is replaced with a display panel 10B, the reflective polarization layer 31 thereof is replaced with a multilayered structural body 30, and the multilayered structural body 30 is disposed between the display panel 10B and the light source 20.

The display panel 10B has the same configuration as the parallax panel 10 except that reflective layers 11B and light-blocking layers 12B are stacked on one surface side (the display panel 40 side) of the light-transmitting substrate 13 and bonded to the polarization layer 43 with a bonding layer 14 interposed therebetween.

Each reflective layer 11B is the same as the reflective layer 11 except that an end part of the reflective layer 11B in the first direction Dx is rimmed by the light-blocking layer 12B overlapping the reflective layer 11B. Each light-blocking layer 12B is the same as the light-blocking layer 12 except that the light-blocking layer 12B is stacked on one surface of the light-transmitting substrate 13 on which the reflective layers 11B are formed so that the light-blocking layer 12B covers an end part of the corresponding reflective layer 11B in the first direction Dx. The bonding layer 14 is a film-like bonding layer such as an optical clear resin (OCR) and improves image appearance by reducing occurrence of interface reflection that would occur when air exists between the light-transmitting substrate 13 and the bonding layer 14.

FIG. 9 is a schematic diagram illustrating an exemplary configuration of the multilayered structural body 30. The multilayered structural body 30 includes the reflective polarization layer 31, a polarization layer 32, and a diffusion layer 33. These components of the multilayered structural body 30 are arranged, for example, in the order of the reflective polarization layer 31, the diffusion layer 33, and the polarization layer 32 from the light source 20 side toward the light-transmitting substrate 13 side. The polarization layer 32 has the same configuration as the polarization layer 43. In the configuration illustrated in FIG. 8, the first polarization component transmitted through the reflective polarization layer 31 and the polarization layer 32 (refer to FIG. 9) of the multilayered structural body 30 is identical to a polarization component transmitted through the polarization layer 43. The diffusion layer 33 has the same configuration as the diffusion layer 24.

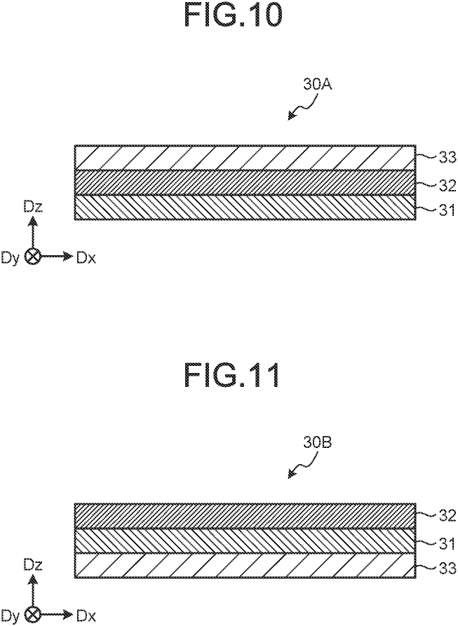

The stacking order of the reflective polarization layer 31, the polarization layer 32, and the diffusion layer 33 illustrated in FIG. 9 is not limited to the above-described order. The multilayered structural body 30 illustrated in FIG. 8 may be replaced with a multilayered structural body 30A illustrated in FIG. 10 or a multilayered structural body 30B illustrated in FIG. 11.

FIG. 10 is a schematic diagram illustrating an exemplary configuration of the multilayered structural body 30A. The multilayered structural body 30A is the same as the multilayered structural body 30 except that components are arranged in the order of the reflective polarization layer 31, the polarization layer 32, and the diffusion layer 33 from the light source 20 side toward the light-transmitting substrate 13 side.

FIG. 11 is a schematic diagram illustrating an exemplary configuration of the multilayered structural body 30B. The multilayered structural body 30B is the same as the multilayered structural body 30 except that components are arranged in the order of the diffusion layer 33, the reflective polarization layer 31, and the polarization layer 32 from the light source 20 side toward the light-transmitting substrate 13 side.

FIG. 12 is a graph illustrating difference in the luminance of a pixel Spix among a case in which the multilayered structural body 30 is disposed between the display panel 10B and the light source 20 in the configuration described above with reference to FIG. 8, a case in which the multilayered structural body 30A is disposed therebetween, and a case in which the multilayered structural body 30B is disposed therebetween. A point P1 corresponds to the case in which the multilayered structural body 30 is disposed between the display panel 10B and the light source 20. Points P21, P22, P23, and P24 and a line graph G2 correspond to the case in which the multilayered structural body 30A is disposed between the display panel 10B and the light source 20. A point P3 corresponds to the case in which the multilayered structural body 30B is disposed between the display panel 10B and the light source 20. A line graph G100 illustrates the luminance of a pixel Spix in the reference example.

The graph illustrated in FIG. 12 illustrates the relation between the luminance of a pixel Spix represented by the vertical axis and a Haze value represented by the horizontal axis. The Haze value is a percentage value expressed by Expression (1) below based on total transmittance (TT) and parallel transmittance (PT). The total transmittance (TT) is the transmittance of light transmitted through the diffusion layer 33 from the light source 20 side toward the display panel 10B. The parallel transmittance (PT) is the ratio of parallel light to total light. The parallel light is light transmitted through the diffusion layer 33 without change in the traveling direction between when the light is incident from the light source 20 side and when the light is emitted from the display panel 10B side. The total light is light transmitted through the diffusion layer 33 from the light source 20 side toward the display panel 10B.

Haze (%) = (TT - PT)/TT×100 ... (1)

Any of the points P1, P21, P22, P23, P24, and P3 in FIG. 12 indicates that the luminance of a pixel Spix in the display device 1B in which the multilayered structural body 30 is employed or the multilayered structural body 30A or the multilayered structural body 30B is employed in place of the multilayered structural body 30 is higher than the luminance of a pixel Spix in the reference example, which is illustrated by the line graph G100. The line graph G2 is a regression line of the points P21, P22, P23, and P24. The points P21, P22, P23, and P24 and the line graph G2 indicate a tendency that the luminance of the pixel Spix is lower as the Haze value of the diffusion layer 33 is larger, but the luminance of the pixel Spix in the display device 1B is higher than the luminance of the pixel Spix in the reference example even when the maximum value (100%) of the Haze value is taken into account. In multiple-view in which the pixel Spix is visually recognized at a plurality of viewpoints (for example, the viewpoints En, E(n+1), and E(n+2)), a light-scattering component such as the diffusion layer 33 facilitates improvement of light use efficiency because luminance other than front luminance is also ensured to some extent.

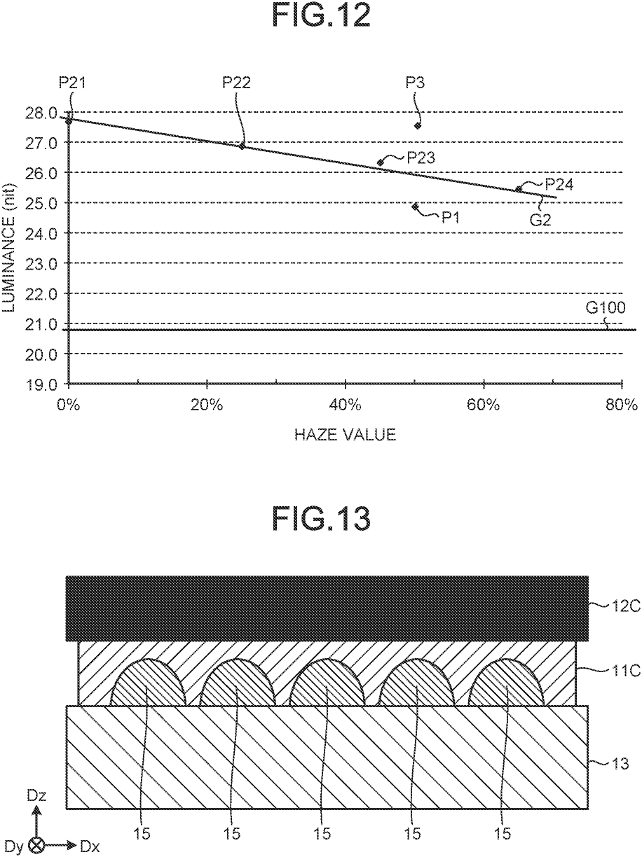

The reflective layers 11 and the light-blocking layers 12, the reflective layers 11A and the light-blocking layers 12A, and the reflective layers 11B and the light-blocking layers 12B described above may be replaced with components such as reflective layers 11C and light-blocking layers 12C illustrated in FIG. 13.

FIG. 13 is a schematic sectional view illustrating an exemplary configuration of each reflective layer 11C and each light-blocking layer 12C. Bumps 15 are provided between the reflective layer 11C and the light-transmitting substrate 13. The bumps 15 are made of an organic layer formed on one surface side of the light-transmitting substrate 13 by a thin-film formation method such as photolithography. The reflective layer 11C is formed by forming a layer that reflects light such as the above-described reflective layer 11 on the one surface side of the light-transmitting substrate 13 on which the bumps 15 have been formed. The relation of each light-blocking layer 12C with the corresponding reflective layer 11C is the same as the above-described relation of each light-blocking layer 12A with the corresponding reflective layer 11A. Specifically, each light-blocking layer 12C is formed such that the light-blocking layer 12C has a greater width in the first direction Dx than the reflective layer 11C overlapping the light-blocking layer 12C in a plan view and covers the reflective layer 11C overlapping the light-blocking layer 12C in a plan view. Each light-blocking layer 12C may be formed to cover the edge of the corresponding reflective layer 11C like each light-blocking layer 12B corresponding to the reflective layer 11B.

Since asperities due to the bumps 15 are formed on a reflection surface of each reflective layer 11C on the light source 20 side, light reflection on the light source 20 side of the light-blocking layer 12C by the reflective layer 11C is made to be diffused reflection. Thus, it is possible to more reliably reduce occurrence of mutual light interference that would be caused by uniform reflection direction and improve light uniformity by light scattering as achieved with the diffusion layer 24 and the diffusion layer 33 described above.

Crosstalk can be more reliably reduced since each light-blocking layer 12B has a greater width in the first direction Dx than the corresponding reflective layer 11B in a plan view. Details thereof will be described below with reference to FIGS. 14 and 15.

FIG. 14 is a schematic diagram illustrating a mechanism that crosstalk is caused by a reflected light L44 generated by a combination of reflection of light L42 by the signal line 45 and reflection of a reflected light L43 by a reflective layer 11D. In the configuration illustrated in FIG. 14, the reflective layer 11D and a light-blocking layer 12D are illustrated as virtual components not provided in reality. The reflective layer 11D is the reflective layer 11 having a greater width in the first direction Dx than the light-blocking layer 12D overlapping the reflective layer 11D in a plan view.

As described above, the signal lines 45 are formed on the first substrate 41. Each of the signal lines 45 is not a component provided for light reflection but causes specular reflection. Thus, like the light L42 in FIG. 14, light incident from the first substrate 41 side through the slit SL is reflected by the signal line 45 and travels toward the reflective layer 11D side like the reflected light L43 in some cases.

If, like the reflective layer 11D, a component that is not covered by the light-blocking layer 12D on the first substrate 41 side is provided, the reflected light L43 is reflected by a surface of the reflective layer 11D on the first substrate 41 side and travels toward the slit SL again as the reflected light L44 in some cases.

Assume that light designed as light to a viewpoint Em is light L41 passing through the slit SL and transmitted through the first pixel Rpix without being reflected by the signal line 45. However, in the example illustrated in FIG. 14, since the above-described reflected light L44 is generated, the reflected light L44 passes through the second pixel Gpix and reaches the viewpoint Em. Thus, the second pixel Gpix, which is not expected to be visually recognized, is visually recognized at the viewpoint Em in addition to the first pixel Rpix, which is expected to be visually recognized. In this manner, light transmitted through the pixel Spix expected not to be visually recognized is unintentionally visually recognized by the user, whereby crosstalk occurs.

FIG. 15 is a schematic diagram illustrating a mechanism that crosstalk is reduced by the light-blocking layer 12B. In the display device 1B described above with reference to FIG. 8, an outer peripheral surface of each reflective layer 11B is covered by the light-blocking layer 12B. Thus, when the reflected light L43 is generated, the reflected light L43 is absorbed by the light-blocking layer 12B and the reflected light L44 illustrated in FIG. 14 is not generated. In this manner, crosstalk is more reliably reduced by the light-blocking layer 12B.

In the similar manner to the light-blocking layer 12B described above with reference to FIG. 15, crosstalk can be more reliably reduced with the light-blocking layer 12A having a greater width in the first direction Dx than the corresponding reflective layer 11A overlapping the light-blocking layer 12A in a plan view. Moreover, when each reflective layer 11 is covered by the corresponding light-blocking layer 12 in a plan view like the light-blocking layer 12 for the reflective layer 11 described above with reference to FIG. 5, crosstalk that is caused by the surface of each reflective layer 11D on the first substrate 41 side described above with reference to FIG. 14 can be reduced.

The reflective layers 11 and the light-blocking layers 12 in the parallax panel 10 described above with reference to FIG. 5 may be replaced with the reflective layers 11A and the light-blocking layers 12A or with the reflective layers 11B and the light-blocking layers 12B. Similarly, the reflective layers 11A and the light-blocking layers 12A described above with reference to FIG. 7 may be replaced with the reflective layers 11B and the light-blocking layers 12B.

The following describes an aspect of the light-blocking layers 12 in a plan view with reference to FIG. 16.

FIG. 16 is a schematic diagram illustrating an exemplary correspondence relation between the arrangement direction of the first pixels Rpix, the second pixels Gpix, and the third pixels Bpix and the extending direction of the light-blocking layers 12 and the slits SL. As illustrated in the “Pixel” column in FIG. 16, the first pixels Rpix, the second pixels Gpix, and the third pixels Bpix are periodically arranged in the order of the first pixel Rpix, the second pixel Gpix, the third pixel Bpix, the first pixel Rpix, the second pixel Gpix, and the third pixel Bpix, ... from one end side in the first direction Dx toward the other end side. In such a configuration, as illustrated in “Example A” column, the light-blocking layers 12 and the slits SL extend along the second direction Dy, for example.

Like light-blocking layers 12H in “Example B” in FIG. 16, light-blocking members (light-blocking layers) may be inclined in the first direction Dx and the second direction Dy. The light-blocking layers 12H has the same configuration as the light-blocking layers 12 except for an extending direction in a plan view. The inclination of the light-blocking layers 12H in the second direction Dy is, for example, a predetermined angle in the range of 10° to 20°, but not limited thereto and is changeable as appropriate. When light-blocking members extend so as to be inclined in the first direction Dx and the second direction Dy like the light-blocking layers 12H, the extending direction of the slits SL is inclined in the first direction Dx and the second direction Dy as well. With light light-blocking members extending so as to be inclined in the first direction Dx and the second direction Dy like the light-blocking layers 12H, it is possible to reduce moire more reliably.

The relation between the light-blocking layers 12 or 12H and the slits SL described above with reference to FIG. 16 is also applicable to the relation between the light-blocking members SM and the slits SL described above with reference to FIGS. 2 and 3.

As described above, a display device (any of the display devices 1, 1A, and 1B) according to the present disclosure includes a plurality of pixels (pixels Spix) arranged in a first direction (for example, the first direction Dx); a light source (the backlight BL or the light source 20) configured to emit light to the pixels; a light blocking member (any of the light-blocking member SM and the light-blocking layers 12, 12A, 12B, and 12C) disposed between the pixels and the light source and having slits (slits SL) extending in a direction intersecting the first direction; a first reflector (the reflective member 21) that faces the light-blocking member with the light source in between and reflects light to the light-blocking member; a second reflector (any of the reflective layers 11, 11A, 11B, and 11C) that covers at least part of the light source side of the light-blocking member and reflects light to the light source; and a reflective polarizer (the reflective polarization layer 31) that is disposed between the first reflector and the pixels, transmits light (the first polarization component) polarized in a second direction, and reflects light (the second polarization component) polarized in a direction intersecting the second direction.

According to the present disclosure, the light-blocking member (any of the light-blocking member SM and the light-blocking layers 12, 12A, 12B, and 12C) limits the path of light emitted from the light source (the backlight BL or the light source 20) and reaching a plurality of viewpoints (for example, the viewpoints En, E(n+1), and E(n+2)) of a user through the pixels (pixels Spix), and thus images can be individually output to the viewpoints. Moreover, according to the present disclosure, the first reflector (the reflective member 21), the second reflector (any of the reflective layers 11, 11A, 11B, and 11C), and the reflective polarizer (the reflective polarization layer 31) reflect light on the light source side of the pixels and increase the amount of light passing through the slit (the slits SL), and thus light from the light source can be more efficiently used.

In the first example, the reflective polarizer (the reflective polarization layer 31) is disposed between the pixels (the pixels Spix) and the light-blocking member (any of the light-blocking member SM and the light-blocking layers 12, 12A, 12B, and 12C). In the second example, the reflective polarizer (the reflective polarization layer 31) is disposed between the light source (the backlight BL or the light source 20) and the light-blocking member (any of the light-blocking member SM and the light-blocking layers 12, 12A, 12B, and 12C). According to any of the first and second examples, images can be individually output to a plurality of viewpoints, and light from the light source can be more efficiently used.

Since the reflective polarizer (the reflective polarization layer 31) overlaps a diffusion layer (the diffusion layer 33) that diffuses light, light from the light source (the backlight BL or the light source 20) can be more uniformly incident in the entire display region of a display panel (for example, any of the display panels 40 and 40A) in which the pixels (pixels Spix) are disposed.

Since the light-blocking member (any of the light-blocking layers 12A, 12B, and 12C) covers the second reflector (any of the reflective layers 11A, 11B, and 11C) in a plan view from the pixel (pixel Spix) side, occurrence of crosstalk can be more reliably reduced.

Since asperities are formed on the light source (the light source 20) side of the second reflector (the reflective layer 11C), light from the light source (the backlight BL or the light source 20) can be more uniformly incident in the entire display region of the display panel (for example, any of the display panels 40 and 40A) in which the pixels (pixels Spix) are disposed.

A scheme by which light reaching each viewpoint is limited by using an optical lens called a barrier lens is known as a scheme that is different from that of the present disclosure and by which images are output to a plurality of viewpoints. However, the barrier lens has a complicate structure and expensive. Furthermore, with the scheme using the barrier lens, optical constraints are strict because a focal point needs to be precisely determined. Thus, it is difficult to individually output images to three viewpoints or more, and it tends to be difficult to achieve excellent display quality as well as the individual image output. However, according to the present disclosure, it is possible to individually output images to multiple viewpoints with a simpler structure than in the scheme using the barrier lens, and it is easier to ensure display quality. In addition, according to the present disclosure, it is possible to more efficiently use light from the light source (the light source 20) as described above.

The polarization component transmitted through the polarization layer 43 and the polarization component transmitted through the polarization layer 44 are, for example, orthogonal to each other, but the relation thereof is not limited thereto and is changeable as appropriate in accordance with the method of driving the liquid crystal employed in the display panel 40. The first polarization component transmitted through the reflective polarization layer 31 has the same polarization direction as the polarization component transmitted through the polarization layer 43. However, when the reflective polarization layer 31 also functions as the polarization layer 43, the first polarization component transmitted through the reflective polarization layer 31 corresponds to a combination of the liquid crystal drive method and the polarization component transmitted through the polarization layer 44. Specifically, in this case, the first polarization component transmitted through the reflective polarization layer 31 is determined so that light transmittance control at the pixels Spix depends on orientation control of the liquid crystal at the pixels Spix. Thus, the first polarization component transmitted through the reflective polarization layer 31 (the second direction) is a direction extending along a plane orthogonal to the third direction Dz and is the same direction (direction in accordance with a combination of the liquid crystal drive method and the polarization component transmitted through the polarization layer 44) as the polarization layer 43.

In a display device that enables image output to a plurality of viewpoints as in the present disclosure, positioning of the pixels Spix and the light-blocking layers 12 are required to be performed at higher accuracy. Since the display panel 40 is provided with a polarization plate, it is highly difficult to perform work such as positioning while checking an alignment mark of the parallax panel 10 through the display panel 40. Thus, the size of the parallax panel 10 in a plan view is made larger than that of the display panel 40 so that the alignment mark indicating the position of the display panel 40 relative to the parallax panel 10 can be checked from the outside not through the display panel 40, which enables easier positioning of the parallax panel 10 and the display panel 40 at high accuracy.

Although three viewpoints (the viewpoints En, E(n+1), and E(n+2)) are exemplarily illustrated in FIGS. 2 and 3 for convenience of description, the number of viewpoints to which images can be individually output with the configuration of the present disclosure is not limited to three but may be two, four, or more. The number of viewpoints to which images can be individually output may be freely determined depending on the relation between the pitch of the pixels Spix in the arrangement direction (for example, the first direction Dx), the width of each light-blocking member SM (light-blocking layer 12) in the first direction Dx, and the width of each slit SL in the first direction Dx.

It should be understood that the present disclosure provides any other effects achieved by aspects described above, such as effects that are clear from the description of the present specification or effects that could be thought of by the skilled person in the art as appropriate.

What is claimed is:

1. A display device comprising:
a plurality of pixels arranged in a first direction;
a light source configured to emit light to the pixels;
a light-blocking member disposed between the pixels and the light source and having slits extending in a direction intersecting the first direction;
a first reflector that faces the light-blocking member with the light source in between and reflects light to the light-blocking member;
a second reflector that covers at least part of the light source side of the light-blocking member and reflects light to the light source; and
a reflective polarizer that is disposed between the first reflector and the pixels, transmits light polarized in a second direction, and reflects light polarized in a direction intersecting the second direction.

2. The display device according to claim 1, wherein the reflective polarizer is disposed between the light-blocking member and the pixels.

3. The display device according to claim 1, wherein the reflective polarizer is disposed between the light source and the light-blocking member.

4. The display device according to claim 3, wherein the reflective polarizer overlaps a diffusion layer that diffuses light.

5. The display device according to claim 1, wherein the light-blocking member covers the second reflector in a plan view from the pixel side.

6. The display device according to claim 1, wherein asperities are formed on the light source side of the second reflector.
